(19) United States
(12) Patent Application Publication
(10) Pub. No.: US 2004/0134680 A1
(43) Pub. Date: Jul. 15, 2004

(54) Use of perimeter stops to support solder interconnects between integrated circuit assembly components

(76) Inventors: Xiang Dai, Roseville, CA (US); Mumtaz Hussain, Fort Collins, CO (US); Stephen Daniel Cromwell, Penryn, CA (US); Russell Lewis, Fort Collins, CO (US); Laszlo Nobi, Fort Collins, CO (US)

Correspondence Address: HEWLETT-PACKARD COMPANY, Intellectual Property Administration, P.O. Box 272400, Fort Collins, CO, 80527-2400, US

(21) Appl. No.: 10/339,842

(22) Filed: Jan. 9, 2003

(51) Int. Cl. H05K 1/03

(52) U.S. Cl. 174/255

(57) ABSTRACT

An assembly is provided having a first circuit board and a second circuit board, each circuit board having a plurality of electrical connection points, electrical connection points on the first circuit board being connected to specified electrical connection points on the second circuit board by solder structures, the first and second circuit boards being stacked with respect to each other and with a defined standoff distance there between, the assembly comprising one or more stops having an inserted portion placed between the first and second circuit board along the perimeter of at least one of the electrical circuit boards, the inserted portion of each of the stops having a fixed, predetermined height.

### BACKGROUND OF THE INVENTION

1. Field of the Invention

The present invention is directed to methods and components used to support solder interconnects between integrated circuit assembly components.

2. Description of the Related Art

To provide a higher level of functionality to an integrated circuit (IC) device, an IC package is electrically connected to a circuit board, for example a daughter card or a mother board. Common techniques for providing electrical terminations on a daughter board include, for example, the use of Ball Grid Array (BGA) solder ball terminations or a Column Grid Array (CGA) on a lower surface of the package substrate. These electrical terminations are then preferably soldered to the mother board using solder columns or other means of attachment including solder or other electrically-conductive attachment means.

The trend toward larger, more complex integrated circuits and board assemblies, and the requirement for higher heat dissipation has necessitated the use of large, heavy heat sinks to dissipate the energy generated during operation of the circuits and assemblies, and compressive retention loads to assure adequate heat transfer at component interfaces. However, mounting of heat sinks on the assemblies, and the attachment of compressive loads, can impose high stresses on the solder balls, solder columns or other means of electrical connection. This can result in excess cold flow, or flow when heat is generated as a result of IC operation, of the solder balls, columns, or connections. Additionally, the connections may be disrupted as a result of shock and vibration during shipping, handling or use of devices incorporating the IC assembly. Devices incorporating BGA, CGA or other electrical connections of limited flexibility, are particularly prone to mechanical damage from use, assembly or bending of the components as a result of the stresses applied, particularly at the corners or perimeters of the board, by assembly components designed to maintain electrical interconnects.

A further problem is that an assembly includes a fairly rigid structure of solder spheres, columns or films, which provide little compliance between the package and the board. During operation heat can build up and a temperature differential can develop between the various components. The constant heating and cooling as the device is turned on and off or power is cycled, particularly when the device is under a mechanical load, places additional stress on the solder attachment points. These problems are apparent under normal operating and life cycles of such devices (typically 20°-100° C. and <2000 cycles). However, they become an increasing problem as operating requirements are expanded (−40°-125° C. and >2000 cycles). This may be relieved to some extent by constructing a more flexible solder connection for attachment. Attempts to address the thermal expansion and electrical continuity problems have been directed to making the interconnects more compliant as discussed in U.S. Pat. No. 6,370,032 to DiStefano et al and references cited therein. For example, typical solder columns, consistent with such solutions, are a high-lead alloy 0.050″-0.087″ in height and 0.020-0.023″ in diameter. However, even these columns are subject to flow from compressive assembly and stabilization loads.

An alternative approach was to use pins of a fixed length attached to a substrate with lower ends of the pins inserted into holes in a printed circuit (PC) board. U.S. Pat. No. 6,395,991 to Dockerty et al is directed to an integrated circuit package which has an array of high melting temperature solder columns to provide electrical interconnections. Specifically, a plurality of much larger diameter, high melting temperature solder columns are positioned at perimeter locations of the substrate upon which the chip is located, these larger columns replacing the pins. The columns are then permanently attached to both the substrate and the PC board. This approach requires additional processing to attach the larger solder columns on the package substrate and consumes a significant amount of package substrate space and board space for the stress relief to be effective. It also requires a different package design and a different board design than what is necessary only to meet electrical interconnection needs. Since the larger columns are also made of solder, they too can exhibit excessive creep under higher loads.

### SUMMARY OF THE INVENTION

One embodiment of the present invention is an assembly having a first circuit board and a second circuit board, each circuit board having a plurality of electrical connection points, electrical connection points on the first circuit board being connected to specified electrical connection points on the second circuit board by solder structures, the first and second circuit boards being stacked with respect to each other and with a defined standoff distance there between, the assembly comprising stops one or more having an inserted portion placed between the first and second circuit board along the perimeter of at least one of the electrical circuit boards, the inserted portion of each of the stops having a fixed, predetermined height.

### BRIEF DESCRIPTION OF THE DRAWINGS

The foregoing and other objects, features and advantages of the invention will be evident to those skilled in the art from the detailed description, below, taken together with the accompanying drawings, in which:

FIG. 1 is a top schematic view of an embodiment of an integrated circuit (IC) package incorporating features of the invention.

FIG. 2 is a cross-sectional view taken along line 22 of FIG. 1, schematically showing a first embodiment of a printed circuit board assembly incorporating solder, column interconnects with perimeter stops consistent with the teachings of the invention.

FIG. 3 is a cross-sectional view taken along line 22 of FIG. 1, showing a second embodiment of the invention.

FIG. 4 is a cross-sectional view taken along line 22 of another embodiment of an IC package incorporating features of the invention.

### DETAILED DESCRIPTION

Use of solder column grid array and ball grid array interconnections are useful approaches for the attachment of stacked ceramic IC packages to PC boards. They are cost-effective when compared to socketed interconnection. However, these solder connection techniques, as well as other types of solder or electrically conductive interconnects, especially the use of tall and thin solder columns, are susceptible to damage due to short-term dynamic load as a result of shock and vibration, as well as creep under long-term static compressive load. In particular, many IC package applications require high retention loads to achieve adequate thermal interface and to prevent shock and vibration damage to the package and interconnects when large heat sinks are used. These high retention loads are usually greater than the maximum long-term compressive load the solder interconnects can withstand. Typically, for a 90/10 lead/tin solder, 5-50 grams per column or ball are used depending on column or ball diameter, respectively, and end-use conditions. However, these compressive loads can cause excessive creep in turn causing interconnect failure, shorting and/or significant reduction in the efficacy of the retention load. This constraint has limited the application of solder interconnect technology. Using perimeter stop as described herein and consistent with the teachings of the invention, to support solder interconnects between stacked boards, eliminates or minimizes maximum retention load constraints and enables a wide variety of solutions to address heat transfer concerns without compromising operational reliability.

Also, by using the perimeter stops to support the retention load for the heat transfer means, the integrity of the solder interconnects used in the assembly of IC packages are not compromised by the compressive load on the interconnects.

One advantage over other mechanical support approaches for solder interconnects is the ability to readily accomplish solder column and BGA rework. Embodiments of the invention enable simple assembly. A further advantage is that placement of the perimeter stops consume very little PCB space.

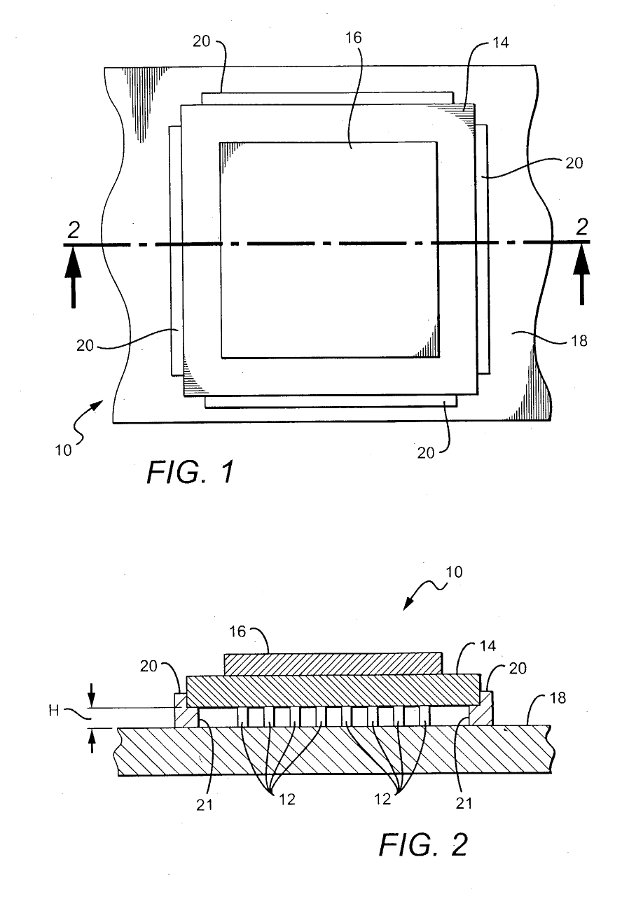

FIG. 1 shows an embodiment of the invention applied to an IC package 10 which comprises a substrate 14, upon which is mounted a chip 16, the substrate being spaced from (stacked above or below) a PC board 18. Four stops 20 rest on the PC board 18 and are positioned along and partially under all four sides of the substrate 14. FIG. 2 is a cross-sectional view, taken along line 2-2 of FIG. 1, showing a first embodiment 20 which uses solder column interconnects 12.

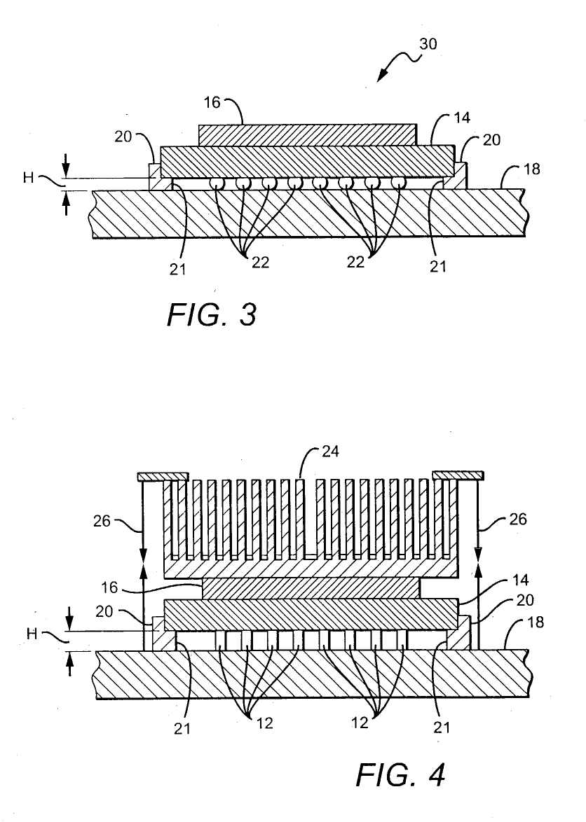

FIG. 3 is a cross-sectional view also taken along line 2-2 of FIG. 1 showing a second embodiment 30 that incorporates a solder ball 22 grid array instead of the solder column interconnects 12.

FIG. 4 is a cross-sectional view of the embodiment of FIG. 2, additionally including a heat sink 24 mounted on top of the chip 16-substrate 14 assembly. The heat sink can be mounted to the IC package 10 by any of the numerous techniques used in the industry for application of compressive loads to assure adequate heat transfer, and/or electrical continuity. Retention load 26, schematically represented in FIG. 4, include, but are not limited to, mechanical clamps, bolts, springs, load plates, and combinations thereof. One skilled in the art will recognize that IC packages can be assembled without retention loads and that other components, such as clamping plates and backing plates, can be added to the assembly. Also, while only eight solder columns or solder balls are shown, these represent only a portion of the grid of interconnects; such assemblies typically includes tens, hundreds or thousands of such electrically conductive interconnects.

Stops 20 have a shelf portion 21 of height H, preferably equal to or slightly less than the operating (assembled) standoff height of the solder columns or solder balls. The height is typically up to about 12 mils less than solder columns and up to about 6 mils less than solder balls. A preferred height is 1 to 6 mils. Most preferably, the height is about 2 mils shorter than the standoff height. This shelf portion 21 is positioned between the stacked substrate and PC board. The selected height H of the shelf 21 can also depend on the standoff tolerance (the allowed variability) used in fabrication. Following solder attachment of the IC package; the heat sink and retention load are assembled to the package. It is preferred that the stops be inserted after the solder attachment and the heat sink assembly is applied, and before the retention load is applied to the heat sink assembly. However, stops with shelf 21 dimensioned to take into account the creep from the retention load can alternatively be placed into the package before the heat sink or after the retention load are applied. The stops support the substrate and relieve the compressive load on interconnects once the solder creeps the intended amount, the substrate resting on the stops.

In one embodiment of a stacked assembly, the standoff height of the solder columns before the designed creep occurs is from about 84 to about 92 mils. With the stop height H being from about 80 to about 84 mils. For 40 mils pitch solder ball interconnects, the standoff height is from about 30 to about 33 mils. And the stop height H is from about 26 to about 30 mils.

A wide variety of materials, preferably metals, metal alloys, plastics or composites can be used to fabricate the stops 20. However, the material should be selected so that it does not compress or flow under the loads applied to stops 20 by the heat sink and retention load. The stops should also have thermal stability under all operating conditions to which the IC package may be exposed and structural stability to withstand compression or distortion as a result of the retention loads that may be constant or fluctuate as the IC package is stressed during use. In a preferred embodiment, the stop, or at least the shelf portion of the stop, that is inserted under the substrate, has a thermal expansion similar to the solder interconnects so differential expansion or contraction is minimized during thermal cycling of the assembly. In the temperature range of from about 0° C. to about 100° C., a preferred expansion of the support structure is from about 0.2% to about 0.3%. The coefficient of thermal expansion for Lead-Tin-based solder is typically from 24 to about 29 ppm/° C. over the temperature range of 15° C. to about 110° C.

Preferred materials of construction of stops 20 include, but are not limited to, various aluminum alloys, magnesium alloys, epoxy novolac molding compounds, stainless steel fiber filled Polyphenylene Sulfide (PPS), 60% glass fiber-filled nylon composites, 40% glass fiber-filled polyethersulfone (PES) composite structures, or combinations thereof. Also, while the perimeter stops 20 have been shown as four pieces, one on each side of a square substrate, multiple stops can be used on each side, for example with spaces in-between, to allow heat generated by the package to dissipate. As a further alternative, rather than being a solid structures, the stops 20 may have holes there through, also designed to provide air circulation and heat dissipation. Also, it is not necessary that the length or number of stops 20 on each side be the same as long as they are properly position to support the substrate and to prevent unacceptable bending of the substrate under the loads or thermal stress applied to the package.

In a first embodiment of a method of assembly of the stacked package incorporating the stops, the chip and substrate are assembled and the interconnects between the substrate and the PC board are soldered. Stops 20 with desired height H are placed along the perimeter between the substrate and board. The heat sink and compression load are then attached. To assure that the stops do not move as a result of thermal expansion or contraction or handling during use of the package, the stops may be secured to either or both of the board and the substrate using any of numerous attachment techniques available to those skilled in the art, including adhesives, mechanical fasteners and interlocks between the various components (pins, pegs, etc) or soldering. Once the initial creep has occurred, the substrate-board spacing is substantially the same as the stop height H and the stops are held in place by the compressive load.

In alternative embodiments the stops can be inserted after other steps in the process, for example after placement of the heat sink or after attachment of the compression load.

To demonstrate the effectiveness of the use of the perimeter stop, assemblies substantially as shown in FIG. 4 were assembled. The reliability and stability of this construction was compared to a like number of substantially similar assemblies that did not include the perimeter stops.

Each assembly had 1657 or 2533 interconnects through solder columns with a nominal height of 88 mils. In the stacked assemblies assembled substantially according to FIG. 4, perimeter stops of nominal shelf height H of 82 mils were placed after soldering of the columns and followed by the attachment of the heat sink and retention load. All assemblies were than subjected to accelerated temperature cycling from O° C. to 100° C. at about 1 hour/cycle.

The assemblies without perimeter stops showed extensive solder column flow with column height reductions averaging about 45% after 2000 cycles. Extensive electrical shorts were observed, usually across the entire array. In contrast, in a tested embodiment, the assemblies incorporating the perimeter stops maintained a package-to-board spacing of 82 mils and after 2000 cycles showed no failures as a result of electrically shorting (a single electrical short per assembly is considered to be a failure).

The assembly techniques and support components are not limited to use with solder columns or solder BGA but may be applied to any assembly wherein multiple electrical outputs on a first circuit board are interconnected to selected multiple electrical inputs on a second circuit board generally positioned in a stacked arrangement.

While reference has been made to chips, substrates, IC packages, daughter cards, mother boards, etc., it is not intended that the invention be limited to the assembly of the specific components mentioned. The invention contemplates the stabilization of two electrical components which are interconnected in a fixed, stacked, roughly parallel construction, each component bearing numerous electrical connection points, where the connection points are interconnected using a solder structure. The stabilization of the assembled structure is accomplished by using supports inserted between the two components around the perimeter of at least one of the components. While individual stops are shown along the periphery of each side of a square or rectangular circuit board, the invention includes the use of single stops extending along two or more sides of the circuit board, for example, under the four corners of the board, or along all four sides, or stops positioned only on two opposing sides of the periphery. One skilled in the art will also recognize that use of the perimeter stops can have additional advantages. For example, the stops can provide shielding from external electromagnetic forces, function as electrical and/or thermal insulators, and defer conductive particles from entering the interboard space.

I claim:

1. An assembly having a first circuit board and a second circuit board, each circuit board having a plurality of electrical connection points, electrical connection points on the first circuit board being connected to specified electrical connection points on the second circuit board by solder structures, the first and second circuit boards being stacked with respect to each other and with a defined standoff distance there between, the assembly comprising one or more stops having an inserted portion placed between the first and second circuit board along the perimeter of at least one of the electrical circuit boards, the inserted portion of each of the stops having a fixed, predetermined height.

2. The assembly of claim 1 wherein the solder structure is a solder ball or a solder column.

3. The assembly of claim 1 wherein the first circuit board is a substrate with a chip attached thereto and the second circuit board is a PC board.

4. The assembly of claim 1 wherein the inserted portion of the stop has a maximum height of from 0 to 12 mils less than the minimum standoff distance selected for the particular solder structure.

5. The assembly of claim 1 wherein at least the inserted portion of the stop is fabricated from a material having substantially the same thermal expansion properties as the solder structure.

6. The assembly of claim 1 wherein the stop is fabricated from a material selected from the group consisting of metals, metal alloys, plastics and composites, and combinations thereof.

7. The assembly of claim 1 wherein the stop is fabricated from a material selected from the group consisting of aluminum alloys, magnesium alloys, epoxy novolac molding compounds, stainless steel fiber-filled polyphenylene Sulfide (PPS), 60% glass fiber-filled nylon composites, 40% glass fiber-filled polyethersulfone (PES) composite structures, and combinations thereof.

8. The assembly of claim 1 wherein the stop has an inserted portion height of from about 0 to about 6 mils less than the minimum defined standoff distance for the solder structure selected.

9. The assembly of claim 1 wherein multiple stops are inserted along at least one side of the perimeter of the electrical circuit boards.

10. The assembly of claim 1 wherein one or more of the stops V have holes therethrough.

11. The assembly of claim 1 wherein the number of stops, length of each stop and position of each stop on each side of the perimeter of the circuit board are different.

12. The assembly of claim 1 wherein the stops are inserted along two opposing edges of the perimeter of the at least one circuit board.

13. The assembly of claim 1 wherein the one or more stops comprises a single stop extending along at least opposing edges and an intermediate edge of the perimeter of the circuit board.

14. A support structure for use in stabilizing two stacked spaced-apart circuit boards with electrical contacts thereon, the circuit boards in electrical communication by solder interconnects, the support structure comprising multiple stops, each having an insertable shelf portion for placement between the circuit boards along each side of the perimeter of one of said boards.

15. The support structure of claim 14 wherein the solder interconnect is a solder column or a solder ball.

16. The support of claim 14 wherein the height of the shelf portion is from about 0 to about 14 mils less than a minimum solder interconnect standoff height.

17. The support structure of claim 14 wherein the height of the shelf portion is from about 0 to about 6 mils less than a minimum solder interconnect standoff height.

18. The support structure of claim 14 wherein the stop is fabricated from a material selected from the group consisting of metals and metal alloys, plastics and composites.

19. The support structure of claim 14 wherein the stop is fabricated from a material selected from the group consisting of aluminum alloy, magnesium alloy, epoxy novolac molding compound, stainless steel fiber-filled polyphenylene Sulfide (PPS), 60% glass fiber-filled nylon composite, 40% glass fiber-filled polyethersulfone (PES) composite structures and combinations thereof.

20. The support structure of claim 14 wherein the change in height of the shelf as the temperature thereof varies from 0° C. to 100° C. is no more than 0.4% and no less than 0.1%.

21. The support structure of claim 14 wherein more than one stops are placed along one or more of the sides of the electrical circuit boards.

22. The support structure of claim 14 wherein one or more of the stops have holes therethrough.

23 The support structure of claim 14 wherein the number of stops, length of each stop and position of each stop along the side of the circuit board are different.

24 A method of minimizing disruption of electrical continuity between stacked integrated circuit boards joined by solder interconnects, each circuit board having lateral dimensions defined by a perimeter, comprising:
forming solder interconnects between electrical contacts on the stacked integrated circuit boards to form a stacked assembly with electrical communication between the boards,
mounting a heat sink to one of the boards, applying a retention load to the stacked assembly, and
placing multiple stops along the perimeter of one of the parallel circuit boards and extending between the boards in the stacked assembly, the stops having a height substantial equal to the height of the solder interconnects after a predetermined creep has occurred.

25. The method of claim 24 wherein the multiple stops are placed before mounting of the heat sink to the parallel assembly.

26. The method of claim 24 wherein the multiple stops are placed before applying the retention load.

27. The method of claim 24 wherein the multiple stops are placed after applying the retention load but prior to the predetermined creep occurring.
